(19) United States
(12) Patent Application Publication
(10) Pub. No.: US 2009/0085674 A1
(43) Pub. Date: Apr. 2, 2009

(54) METHOD AND SYSTEM FOR SIGNAL GENERATION VIA A PLL WITH DIGITAL PHASE DETECTION

(76) Inventor: Ahmadreza Rofougaran, Newport Coast, CA (US)

Correspondence Address: MCANDREWS HELD & MALLOY, LTD, 500 WEST MADISON STREET, SUITE 3400, CHICAGO, IL, 60661, US

(21) Appl. No.: 11/863,871

(22) Filed: Sep. 28, 2007

(51) Int. Cl. H03L 7/085

(52) U.S. Cl. 331/18

(57) ABSTRACT

Aspects of a method and system for signal generation via a PLL with a digital feedback path are provided. In this regard, an output of a VCO may clock an accumulator to generate a digital feedback signal for phase comparison with a digital reference signal, wherein a value of a digital control word is added to a value stored in said accumulator on each cycle of said VCO output. The phase comparison may be performed by multiplying the feedback signal and the reference signal. Accordingly, a control voltage of the VCO may be determined based on a product of the multiplication. The value of the control word may be programmatically controlled and may be determined based on a frequency of the VCO output and/or of the reference signal. In this regard, the value of the control word may be retrieved from a look-up table.

### CROSS-REFERENCE TO RELATED APPLICATIONS/INCORPORATION BY REFERENCE

Not Applicable

### FIELD OF THE INVENTION

Certain embodiments of the invention relate to signal processing. More specifically, certain embodiments of the invention relate to a method and system for signal generation via a PLL with a digital feedback path.

### BACKGROUND OF THE INVENTION

As wireless communications continue to evolve and become increasingly relied upon for the conveyance of data, new challenges continue to face wireless system designers. In this regard, the increasing number of wireless technologies and wireless devices has led to increasing congestion in many frequency bands. Accordingly, efforts exist to utilize less congested frequency bands. For example, in 2001, the Federal Communications Commission (FCC) designated a large contiguous block of 7 GHz bandwidth for communications in the 57 GHz to 64 GHz spectrum. This frequency band was designated for use on an unlicensed basis, that is, the spectrum is accessible to anyone, subject to certain basic, technical restrictions such as maximum transmission power and certain coexistence mechanisms. The communications taking place in this band are often referred to as ‘60 GHz communications’. However, in order to transmit, receive, and/or process signals with such high frequencies as 60 GHz, new methods and systems for signal generation are necessary. In this regard, conventional methods of signal generation, such as integer-N and Fractional-N phase locked loops may be difficult or costly to implement as frequencies increase.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for signal generation via a PLL with a digital feedback path, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating an exemplary PLL with digital phase detection, in accordance with an embodiment of the invention.

FIG. 2 is a flow chart illustrating exemplary steps for generating a signal via a PLL controlled with digital phase detection, in accordance with an embodiment of the invention.

FIG. 3 is a diagram of a transceiver comprising a local oscillator generator (LOGEN) which may comprise a PLL with digital phase detection, in accordance with an embodiment of the invention.

FIG. 4 is a block diagram illustrating an exemplary RF communication device, in accordance with an embodiment of the invention.

### DETAILED DESCRIPTION OF THE INVENTION

Certain embodiments of the invention may be found in a method and system for signal generation via a PLL with a digital feedback path. In this regard, an output of a VCO may clock an accumulator to generate a digital feedback signal for phase comparison with a digital reference signal, wherein a value of a digital control word is added to a value stored in said accumulator on each cycle of said VCO output. The phase comparison may be performed by multiplying the feedback signal and the reference signal. Accordingly, a control voltage of the VCO may be determined based on a product of the multiplication. The value of the control word may be programmatically controlled and may be determined based on a frequency of the VCO output and/or of the reference signal. In this regard, the value of the control word may be retrieved from a look-up table. The VCO output may be frequency divided prior to clocking the accumulator and the divisor of the frequency division may be based on a frequency of the VCO output and the reference signal. The digital reference signal may be generated via an accumulator clocked by a stable reference oscillator.

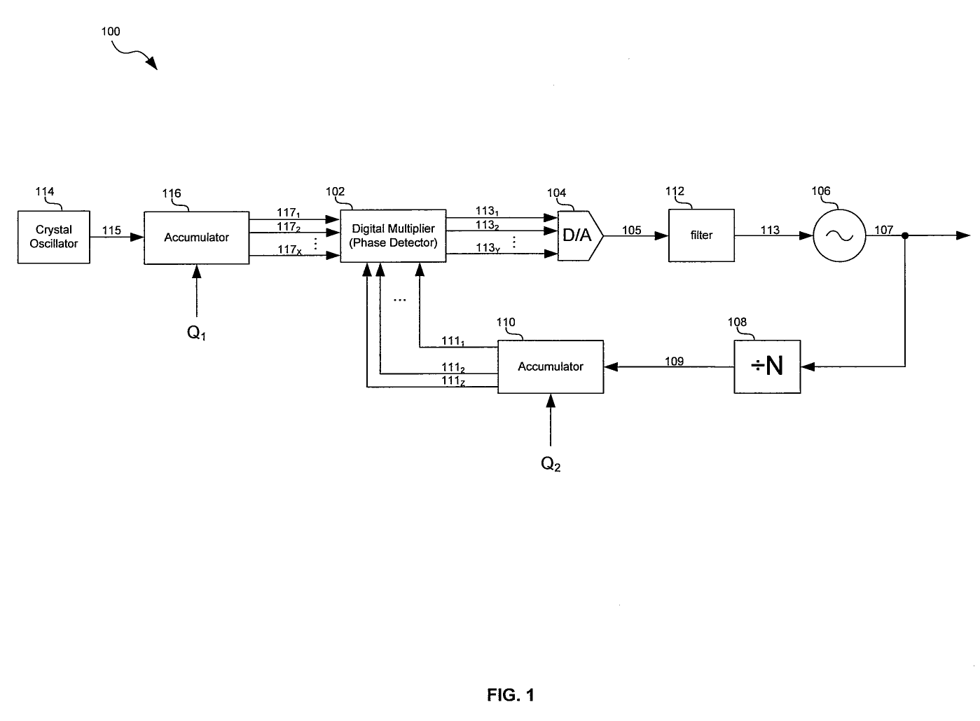

FIG. 1 is a block diagram illustrating an exemplary PLL with digital phase detection, in accordance with an embodiment of the invention. Referring to FIG. 1 an exemplary PLL may comprise a crystal oscillator 114, an analog-to-digital converter (A/D) 116, a digital multiplier 102, a digital-to-analog converter (D/A) 104, a voltage controlled oscillator (VCO) 106, a frequency divider 108, an accumulator 110, and a filter 112.

The crystal oscillator 114 may comprise suitable logic, circuitry, and/or code that may enable generating a stable (within determined limits) reference frequency.

The accumulator 116 may comprise suitable logic, circuitry, and/or code that may enable successively adding a control word Q1 to a value stored in the accumulator on each cycle of a reference clock. The accumulator 116 may receive the control word Q₁ and a reference signal. In this regard, the control word Q₁ and the reference signal may determine a phase and/or a frequency of the output signal 117. In an exemplary embodiment of the invention, the accumulator 116 may be clocked by the crystal oscillator 114. The control word Q₁ may be successively added to a value stored in the accumulator 116 on each cycle of the signal 115. In this manner, the sum may eventually be greater than the maximum value the accumulator may store, and the value in the accumulator may overflow or “wrap”. Accordingly, an n-bit accumulator may overflow at a frequency fₒ given by EQ. 1.

fₒ=f₁₁₅(Q₁/2ⁿ) EQ. 1

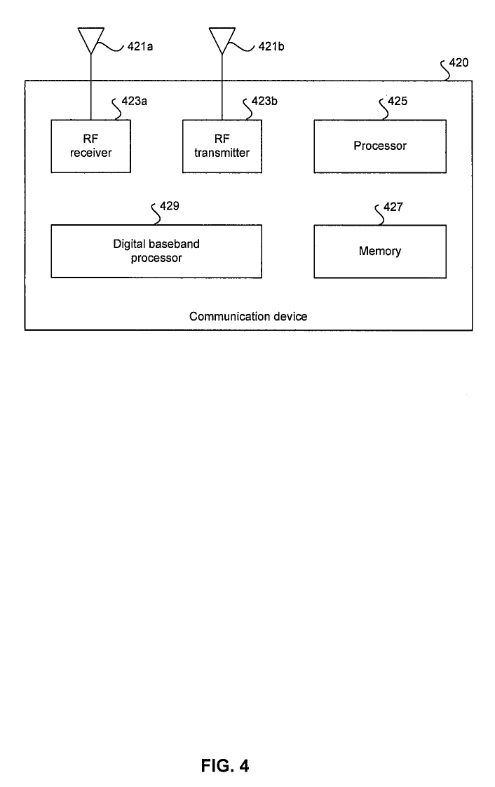

In this manner, the output of the accumulator, θ, may be periodic with period 1/fₒ. Additionally, the control word, Q₁, may be provided by, for example, the processor 425 of FIG. 4. In this regard, possible values of the control word may be generated based on possible values of the reference frequency 115 and the desired frequency of the signal 107. Values of the control word Q₂ may be stored in, for example, a look up table in the memory 427 of FIG. 4.

The digital multiplier 102 may comprise suitable logic, circuitry, and/or code that may enable multiplying the digital signals 111 and 117 and outputting the product as the signal 113. An average value of the signal 113 may be utilized to determine a phase difference between the signals 111 and 117. In this regard, an average value of 0 may indicate the signals 111 and 117 are in-phase, while a non-zero average value of the signal 113 may indicate a phase difference between the signals 111 and 117.

The D/A 104 may comprise suitable logic, circuitry, and/or code that may enable conversion of digital signals to an analog representation. In this regard, the D/A 104 may, for example, output a voltage proportional to the binary value of an input digital signal. Accordingly, the D/A 104 may receive one or more control signals from, for example, a processor such as the processor 425 of FIG. 4. Moreover, the D/A 104 may receive one or more clock signals. The digital input may comprise one or more bits which may be conveyed serially or in parallel. In the exemplary embodiment shown, the digital bits 113₁, . . . , 113_{y} may be converted into an analog waveform 105.

The filter 112 may comprise suitable, logic, circuitry, and/or code for filtering the analog signal 105 to output a signal 113 which may be indicative of a phase difference between the signals 111 and 117. For example, the filter 112 may be a low pass filter enabled to output the average value of the signal 105. In various embodiments of the invention, additional filtering may be performed digitally on the signal 113 output by the multiplier 102.

The VCO 106 may comprise suitable logic, circuitry, and/or code that may enable generating a signal 107 based on a control signal 113. In this regard, the frequency of the signal 107 may be determined, at least in part, by the voltage of 113.

The frequency divider 108 may comprise suitable logic, circuitry, and/or for receiving a first, higher, frequency and outputting a second, lower, frequency. The scaling factor, N, may be determined based on one or more control signals from, for example, the processor 425 of FIG. 4. In this regard, values for the frequency divider may be stored in, for example, a look-up table in the memory 427 of FIG. 4.

The accumulator 110 may comprise suitable logic, circuitry, and/or code that may enable successively adding a control word Q₂ to a value stored in the accumulator on each cycle of a reference clock. The accumulator 110 may receive the control word Q₂ and a reference signal. In this regard, the control word Q₂ and the reference signal may determine a phase and/or a frequency of the output signal 111. In an exemplary embodiment of the invention, the accumulator 110 may be clocked by the VCO output 107, or, as depicted in FIG. 1, by the signal 109 which may be a divided down version of the VCO output 107. The control word may be successively added to a value stored in the accumulator on each cycle of the VCO output. In this manner, the sum may eventually be greater than the maximum value the accumulator may store, and the value in the accumulator may overflow or “wrap”. Accordingly, an n-bit accumulator may overflow at a frequency fₒ given by EQ. 2.

fₒ=f₁₀₉(Q₂/2ⁿ) EQ.2

In this manner, the output of the accumulator, θ, may be periodic with period 1/fₒ. Additionally, the control word, Q₂, may be provided by, for example, the processor 425 of FIG. 4. In this regard, possible values of the control word may be generated based on possible values of the reference frequency 117 and the output frequency 107, and may be stored in, for example, a look up table in the memory 427 of FIG. 4.

In operation the LOGEN 100 may generate a signal 107 of variable frequency which may have stability similar to the fixed frequency reference signal 115 from the crystal oscillator 114. In this regard, the accumulator 110 may enable generation of, based on the signal 109 and the control word Q₂, a digital signal 111 which may be equal in frequency to the digital reference 117. Accordingly, the output signal 107 may be any integer or fractional multiple of the reference signal 115. In this regard, the signal 111 may be determined using

$${f}_{111} = \frac{{f}_{107}}{N} \cdot {Q}_{2} \cdot \frac{1}{{2}^{n}} \qquad EQ . 3$$

where f₁₁₁ is the frequency of the signal 111, f₁₀₇ is the frequency of the signal 107, N is the divide ratio of the frequency divider 108, Q₂ is the value of the control word input to the accumulator 110, and ‘n’ is the number of bits comprising the accumulator. Accordingly, the LOGEN 100 may be enabled to generate a wide range of frequencies, with high resolution, without the need of a traditional fractional-N synthesizer.

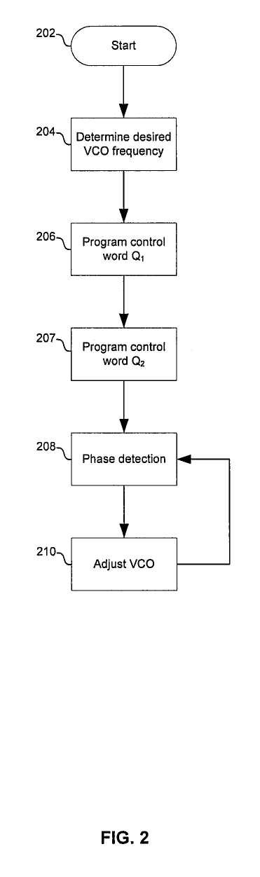

FIG. 2 is a flow chart illustrating exemplary steps for generating a signal via a PLL controlled with digital phase detection, in accordance with an embodiment of the invention. Referring to FIG. 2, the exemplary steps may begin with start step 202. Subsequent to start step 202, the exemplary steps may advance to step 204. In step 204, a desired frequency to be output by the VCO 106 may be determined. In this regard, if the LOGEN 100 is being utilized to transmit or receive RF signals, then the output of the VCO may be determined based on the RF transmit and/or RF receive frequency. Subsequent to step 204, the exemplary steps may advance to step 206. In step 206, the digital control word Q₁ input to the accumulator 116 may be determined. In this regard, the value of the digital control word Q₁may be determined based on a desired reference frequency of the signal 117. Subsequent to step 206, the exemplary steps may advance to step 207. In step 207, the digital control word Q₂ input to the accumulator 110 may be determined. In this regard, the value of the digital control word Q₂ may be determined utilizing EQ. 3 above. Accordingly, for different values of the reference frequency 115 and/or the desired output frequency 107, the value of the digital output word may be adjusted. In this regard, a processor, such as the processor 425 or the processor 429 of FIG. 4, may programmatically control the value of the digital control word.

Subsequent to step 206, the exemplary steps may advance to step 208. In step 208, a phase difference between the signal 111 and the signal 117 may be determined. The phase difference may be determined by multiplying the signals 111 and 117. In this regard, the average value of the product of the signals 111 and 117 may be indicative of a phase difference between the signals 111 and 117. Subsequent to step 208, the exemplary steps may advance to step 210. In step 210, the VCO 106 may be adjusted based on the phase difference between the signals 111 and 117. For example, the voltage across a varactor may be adjusted to increase or decrease the output frequency of the VCO 106, such that the phase difference between the signals 111 and 117 may be reduced. Accordingly, when there may be no phase difference between the signals 111 and 117 the PLL may be said to be “locked”. Subsequent to step 210, the exemplary steps may return to step 208. In this regard, maintaining phase lock may be a continuous process that requires periodic or even constant feedback.

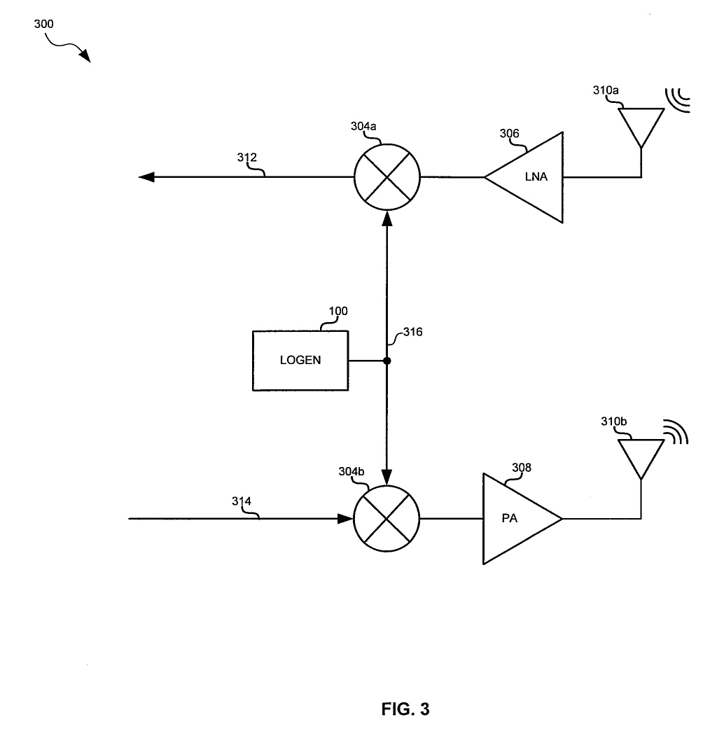

FIG. 3 is a diagram of a transceiver comprising a local oscillator generator (LOGEN) which may comprise a PLL with digital phase detection, in accordance with an embodiment of the invention. Referring to FIG. 3 there is shown a transceiver 300 which may be all or a portion of the RF receiver 423a of FIG. 4, for example. The transceiver 300 may comprise local oscillator generator (LOGEN) 100, mixers 304a and 304b, a low noise amplifier (LNA) 306, a power amplifier 308, and antennas 310a and 310b.

The LOGEN 100 may comprise suitable logic, circuitry, and/or code that may enable generating a reference signal. In this regard, the LOGEN 100 may comprise a phase locked loop (PLL) with digital phase detection. In an exemplary embodiment, of the invention, the transceiver 300 may directly convert between RF and baseband. Accordingly, the frequency of the signal 316, F_{LO}, may be (F_{RF}±F_{baseband}).

The mixer 304a may comprise suitable logic, circuitry, and/or code that may enable generation of inter-modulation products resulting from mixing the output of the LNA 306 and the LO signal 316. Similarly, the mixer 304b may comprise suitable logic, circuitry, and/or code that may enable generation of inter-modulation products resulting from mixing the baseband signal 314 and the LO signal 316. In various embodiments of the invention the output of the mixers may be filtered such that desired inter-modulation products are passed with less attenuation than undesired inter-modulation products.

The LNA 306 may comprise suitable logic, circuitry, and/or code that may enable buffering and/or amplification of received RF signals. In this regard, the gain of the LNA 306 may be adjustable to enable reception of signals of varying strength. Accordingly, the LNA 306 may receive one or more control signals from a processor such as the processors 425 and 429 of FIG. 4.

The PA 308 may comprise suitable logic, circuitry, and/or code that may enable buffering and/or amplification of a RF signal and outputting the signal to an antenna for transmission. In this regard, the gain of the PA 308 may be adjustable and may enable transmitting signals of varying strength. Accordingly, the PA 308 may receive one or more control signals from a processor such as the processors 425 and 429 of FIG. 4.

The antennas 310a and 310b may comprise suitable logic, circuitry, and/or code that may enable reception and/or transmission of signals. In various embodiments of the invention there may be separate transmit and receive antennas, as depicted, or there may be a single antenna for both transmit and receive functions.

In an exemplary receive operation, RF signals may be received by the antenna 310a and may be conveyed to the LNA 306. The LNA 306 may amplify the received signal and convey it to the mixer 304a. In this regard, the gain of the LNA may be adjusted based on received signal strength. Additionally, the gain may be controlled via one or more control signals from, for example, a processor such as the processors 425 and 429. The LO signal 316 may be coupled to the mixer 304a such that the received signal of frequency F_{RF} may be down-converted to a baseband signal 312. The baseband signal 312 may be conveyed, for example, to a baseband processor such as the baseband processor 429 of FIG. 4.

In an exemplary transmit operation, a baseband signal 314 may be conveyed to the mixer 304b. The LO signal 316 may be coupled to the mixer 304b and the baseband signal 314, of frequency F_{baseband}, may be up-converted to RF. The RF signal may be conveyed to the PA 308 for transmission via the antenna 310b. In this regard, the gain of the PA 308 may be adjusted via one or more control signals from, for example, a processor such as the processors 425 and 429 of FIG. 4.

FIG. 4 is a block diagram illustrating an exemplary RF communication device, in accordance with an embodiment of the invention. Referring to FIG. 4, there is shown a RF communication device 420 that may comprise an RF receiver 423a, an RF transmitter 423b, a digital baseband processor 429, a processor 425, and a memory 427. A receive antenna 421a may be communicatively coupled to the RF receiver 423a. A transmit antenna 421b may be communicatively coupled to the RF transmitter 423b. The RF communication device 420 may be operated in a system, such as the cellular network and/or digital video broadcast network, for example.

The RF receiver 423a may comprise suitable logic, circuitry, and/or code that may enable processing of received RF signals. In this regard, the receiver may be enabled to generate signals, such as local oscillator signals, for the reception and processing of RF signals. The RF receiver 423a may down-convert received RF signals to a baseband frequency signal. The RF receiver 423a may perform direct down-conversion of the received RF signal to a baseband frequency signal, for example. In some instances, the RF receiver 423a may enable analog-to-digital conversion of the baseband signal components before transferring the components to the digital baseband processor 429. In other instances, the RF receiver 423a may transfer the baseband signal components in analog form.

The digital baseband processor 429 may comprise suitable logic, circuitry, and/or code that may enable processing and/or handling of baseband frequency signals. In this regard, the digital baseband processor 429 may process or handle signals received from the RF receiver 423a and/or signals to be transferred to the RF transmitter 423b. The digital baseband processor 429 may also provide control and/or feedback information to the RF receiver 423a and to the RF transmitter 423b based on information from the processed signals. The digital baseband processor 429 may communicate information and/or data from the processed signals to the processor 425 and/or to the memory 427. Moreover, the digital baseband processor 429 may receive information from the processor 425 and/or to the memory 427, which may be processed and transferred to the RF transmitter 423b for transmission to the network.

The RF transmitter 423b may comprise suitable logic, circuitry, and/or code that may enable processing of RF signals for transmission. In this regard, the transmitter may be enabled to generate signals, such as local oscillator signals, for the transmission and processing of EHF signals. The RF transmitter 423b may up-convert the baseband frequency signal to an RF signal. The RF transmitter 423b may perform direct up-conversion of the baseband frequency signal to a RF signal of approximately 60 GHz, for example. In some instances, the RF transmitter 423b may enable digital-to-analog conversion of the baseband signal components received from the digital baseband processor 429 before up conversion. In other instances, the RF transmitter 423b may receive baseband signal components in analog form.

The processor 425 may comprise suitable logic, circuitry, and/or code that may enable control and/or data processing operations for the RF communication device 420. The processor 425 may be utilized to control at least a portion of the RF receiver 423a, the RF transmitter 423b, the digital baseband processor 429, and/or the memory 427. In this regard, the processor 425 may generate at least one signal for controlling operations within the RF communication device 420. The processor 425 may also enable executing of applications that may be utilized by the RF communication device 420. For example, the processor 425 may execute applications that may enable displaying and/or interacting with content received via RF signals in the RF communication device 420.

The memory 427 may comprise suitable logic, circuitry, and/or code that may enable storage of data and/or other information utilized by the RF communication device 420. For example, the memory 427 may be utilized for storing processed data generated by the digital baseband processor 429 and/or the processor 425. The memory 427 may also be utilized to store information, such as configuration information, that may be utilized to control the operation of at least one block in the RF communication device 420. For example, the memory 427 may comprise information necessary to configure the RF receiver 423a to enable receiving signals in the appropriate frequency band.

Aspects of a method and system for signal generation via a PLL with digital feedback path are provided. In this regard, an output 107 of the VCO 106 may clock an accumulator 110 to generate a digital feedback signal 111 for phase comparison with a digital reference signal 117, wherein a value of a digital control word Q₂ is added to a value stored in said accumulator 110 on each cycle of said VCO 106 output. The phase comparison may be performed by multiplying the feedback signal 111 and the reference signal 117. Accordingly, a control voltage of the VCO 106 may be determined based on a product of the multiplication. The value of the control word Q₂ may be programmatically controlled and may be determined based on a frequency of the VCO output 107 and/or of the reference signal 115. In this regard, the value of the control word Q₂ may be retrieved from a look-up table, which may, for example, be stored in the memory 427. The VCO output may be frequency divided, to generate the signal 109, prior to clocking the accumulator 110 and the divisor, N, of the frequency division may be based on a frequency of the VCO output and the reference signal. The digital reference signal may be generated via an accumulator clocked by a stable reference oscillator 114.

Another embodiment of the invention may provide a machine-readable storage, having stored thereon, a computer program having at least one code section executable by a machine, thereby causing the machine to perform the steps as described herein for signal generation via a PLL with digital feedback path are provided.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for signal processing, the method comprising:
generating a digital feedback signal for phase comparison with a digital reference signal by clocking an accumulator with an output of a voltage controlled oscillator, wherein a value of a digital control word is added to a value stored in said accumulator on each cycle of said output of said voltage controlled oscillator.

2. The method according to claim 1, comprising determining a phase difference between said feedback signal and said reference signal by multiplying said feedback signal and said reference signal.

3. The method according to claim 2, comprising controlling said voltage controlled oscillator based on a product of said multiplication.

4. The method according to claim 1, comprising determining a value of said digital control word based on said output of said voltage controlled oscillator and based on said reference signal.

5. The method according to claim 1, comprising programmatically controlling said digital control word.

6. The method according to claim 1, comprising acquiring said digital control word from a lookup table (LUT) based on said output of said voltage controlled oscillator and based on said reference signal.

7. The method according to claim 1, comprising frequency dividing said output of said voltage controlled oscillator prior to said clocking of said accumulator, wherein a divisor of said frequency division is based on said output of said voltage controlled oscillator and based on said reference signal.

8. The method according to claim 1, comprising generating said digital reference signal via an accumulator clocked by a reference oscillator.

9. A machine-readable storage having stored thereon, a computer program having at least one code section for signal processing, the at least one code section being executable by a machine for causing the machine to perform steps comprising:
generating a digital feedback signal for phase comparison with a digital reference signal by clocking an accumulator with an output of a voltage controlled oscillator, wherein a value of a digital control word is added to a value stored in said accumulator on each cycle of said output of said voltage controlled oscillator.

10. The machine-readable storage according to claim 9, wherein said at least one code section enables determining a phase difference between said feedback signal and said reference signal by multiplying said feedback signal and said reference signal.

11. The machine-readable storage according to claim 10, wherein said at least one code section enables controlling said voltage controlled oscillator based on a product of said multiplication.

12. The machine-readable storage according to claim 9, wherein said at least one code section enables determining a value of said digital control word based on said output of said voltage controlled oscillator and based on said reference signal.

13. The machine-readable storage according to claim 9, wherein said at least one code section enables programmatically controlling said digital control word.

14. The machine-readable storage according to claim 9, wherein said at least one code section enables acquiring said digital control word from a lookup table (LUT) based on said output of said voltage controlled oscillator and based on said reference signal.

15. The machine-readable storage according to claim 9, wherein said at least one code section enables frequency dividing said output of said voltage controlled oscillator prior to said clocking of said accumulator, wherein a divisor of said frequency division is based on said output of said voltage controlled oscillator and based on said reference signal.

16. The machine-readable storage according to claim 9, wherein said at least one code section enables generating said digital reference signal via an accumulator clocked by a reference oscillator.

17. A system for signal processing, the system comprising:
one or more circuits that enable generation of a digital feedback signal for phase comparison with a digital reference signal by clocking an accumulator with an output of a voltage controlled oscillator, wherein a value of a digital control word is added to a value stored in said accumulator on each cycle of said output of said voltage controlled oscillator.

18. The system according to claim 17, wherein said one or more circuits enable determination of a phase difference between said feedback signal and said reference signal by multiplying said feedback signal and said reference signal.

19. The system according to claim 18, wherein said one or more circuits enable control of said voltage controlled oscillator based on a product of said multiplication.

20. The system according to claim 17, wherein said one or more circuits enable determination of a value of said digital control word based on said output of said voltage controlled oscillator and based on said reference signal.

21. The system according to claim 17, wherein said one or more circuits enable programmatic control of said digital control word.

22. The system according to claim 17, wherein said one or more circuits enable acquisition of said digital control word from a lookup table (LUT) based on said output of said voltage controlled oscillator and based on said reference signal.

23. The system according to claim 17, wherein said one or more circuits enable frequency division of said output of said voltage controlled oscillator prior to said clocking of said accumulator, wherein a divisor of said frequency division is based on said output of said voltage controlled oscillator and said reference signal.

24. The system according to claim 17, wherein said one or more circuits enable generation of said reference signal via an accumulator clocked by a reference oscillator.
